(19) United States
(12) Patent Application Publication
(10) Pub. No.: US 2007/0200140 A1
(43) Pub. Date: Aug. 30, 2007

(54) ELECTROSTATIC PROTECTION DEVICE FOR SEMICONDUCTOR CIRCUIT FOR DECREASING INPUT CAPACITANCE

(76) Inventor: Jang Hoo KIM, Kyoungki-do (KR)

Correspondence Address: LADAS & PARRY LLP, 224 SOUTH MICHIGAN AVENUE, SUITE 1600, CHICAGO, IL, 60604, US

(21) Appl. No.: 11/678,121

(22) Filed: Feb. 23, 2007

(30) Foreign Application Priority Data
Feb. 24, 2006 (KR) 10-2006-0018181

(51) Int. Cl. H01L 29/74

(52) U.S. Cl. 257/173

(57) ABSTRACT

An electrostatic protection device for a semiconductor circuit for protecting an internal circuit from static electricity applied to the pad includes a first conductivity type semiconductor substrate; second conductivity type diffusion regions formed on the surface of the semiconductor substrate at regular intervals into a dot type; isolation structures formed on the surface of the semiconductor substrate to respectively surround the second conductivity type diffusion regions; and first conductivity type diffusion regions formed on the surface of the semiconductor substrate outside of the second conductivity type diffusion regions and the isolation regions.

### CROSS-REFERENCE TO RELATED APPLICATIONS

The present application claims priority to Korean patent application number 10-2006-0018181 filed on Feb. 24, 2006, which is incorporated herein by reference in its entirety.

### BACKGROUND OF THE INVENTION

The present invention relates to an electrostatic protection device for a semiconductor circuit, and more particularly, to an electrostatic protection device for a semiconductor circuit that can decrease input capacitance.

As well known in the art, if a semiconductor integrated circuit (IC) comes into contact with a charged human body or machine, the static electricity stored in the human body or machine is discharged from the external pins through the pad of the integrated circuit into the semiconductor. Such a transient current with high energy can cause significant damage to the internal circuit of the semiconductor. The discharge of the stored static electricity from the semiconductor integrated circuit through the human body or machine also damages the internal circuit of the semiconductor.

In order to protect circuits from being damaged by the discharge of currents, as shown in FIG. 1, electrostatic protection devices are arranged between the pad and the internal circuit of the semiconductor. The electrostatic protection device redirects the static electricity applied to the pad through a ground line (VSS) or a source voltage supply line (VCC) to protect the internal circuit.

A MOS transistor is generally used as the electrostatic protection device; however, the large diffusion region of conventional MOS transistors increases the input capacitance of the semiconductor. As such, the field has relied on use of a diode as an electrostatic protection device since the diode has superior current drivability as compared to the MOS transistor and a diffusion region that can be minimized.

Hereinbelow, a conventional electrostatic protection device comprising a diode will be described with reference to FIG. 2.

FIG. 2 is a plan view illustrating the conventional electrostatic protection device for a semiconductor circuit that comprises a diode. The conventional electrostatic protection device comprising a diode includes second conductivity type diffusion regions 120, each of which is shaped like a bar and formed on the surface of the first conductivity type semiconductor substrate 100, arranged parallel to one another; isolation structures 110, which are formed to surround the second conductivity type diffusion regions 120; and first conductivity type diffusion regions 130, which are formed on the surface of the semiconductor substrate 100 outside of the isolation structures 110.

The first conductivity type diffusion regions 130 are connected to a ground line (VSS) or a source voltage supply line (VCC) through first lines (not shown), and the second conductivity type diffusion regions 120 are connected to a pad through second lines (not shown).

In FIG. 2, the reference numeral 135 designates first contacts, which are formed in the first conductivity type diffusion regions 130 and are connected to the first lines. Reference numeral 125 designates second contacts, which are formed in the second conductivity type diffusion regions 120 and connected to the second lines.

When a diode is used as an electrostatic protection device rather than a MOS transistor, since the capacitance generated upon the input or output of signals is decreased, the signal transmission speed is increased, and signal integrity is improved.

Despite the benefits of using a diode as an electrostatic protection device, limitations nonetheless exist in decreasing input capacitance. When the semiconductor device is highly integrated, since it is difficult to decrease the size of the electrostatic protection device, the parasitic capacitance generated due to the presence of the electrostatic protection device significantly increases in the overall input capacitance. Therefore, the high integration of a semiconductor device increases the operation frequency of the chip and the capacitance of the electrostatic protection device, thereby impeding high-speed operation of the semiconductor device Thus, in order to ensure the high-speed operation of a semiconductor device, it is essential to decrease the capacitance of the electrostatic protection device.

The input capacitance of the electrostatic protection device comprising a diode as shown in FIG. 2 is proportional to the area of the second conductivity type diffusion regions 120, which are connected to the pad. Hence, in order to solve the problems created by the increase of capacitance due to the electrostatic protection device, it is necessary to reduce the area of the second conductivity type diffusion regions 120.

Nevertheless, in the configuration shown in FIG. 2, if the area of the second conductivity type diffusion regions 120 are reduced, the perimeters of the second conductivity type diffusion regions 120 are decreased, thereby deteriorating current drivability and degrading electrostatic protection characteristics.

### SUMMARY OF THE INVENTION

An embodiment of the present invention is directed to an electrostatic protection device for a semiconductor circuit that comprises a diode, which decreases input capacitance without degrading the characteristics thereof.

Further, an embodiment of the present invention is directed to an electrostatic protection device for a semiconductor circuit that is advantageous to high-speed operation due to a minimized input capacitance.

In one embodiment, an electrostatic protection device for a semiconductor circuit, used for protecting the internal circuit from static electricity applied to the pad, comprises a first conductivity type semiconductor substrate; second conductivity type diffusion regions formed on the surface of the semiconductor substrate at regular intervals into a dot type; isolation structures formed on the surface of the semiconductor substrate to respectively surround the second conductivity type diffusion regions; and first conductivity type diffusion regions formed on the surface of the semiconductor substrate outside of the second conductivity type diffusion regions and the isolation regions.

The second conductivity type diffusion regions have the sectional shape of a polygon in which each corner has an angle greater than 90°. Preferably, the polygonal shape of the second conductivity type diffusion regions is that of an octagon.

The second conductivity type diffusion regions have the sectional shape of a quadrangle having rounded corners.

The distance between two second conductivity type diffusion regions adjoining each other is less than the width of each second conductivity type diffusion region.

The electrostatic protection device further comprises first lines connected to the first conductivity type diffusion regions; and second lines connected to the second conductivity type diffusion regions.

The electrostatic protection device further comprises a connection line shaped like a matrix and located between the first conductivity type diffusion regions and the first lines; and connection patterns located between the second conductivity type diffusion regions and the second lines.

The first lines are connected to a ground line or a source voltage supply line.

The second lines are connected to the pad.

The electrostatic protection device further comprises a plurality of first contacts formed on the first conductivity type diffusion regions and connected to the first lines; and a plurality of second contacts formed on the second conductivity type diffusion regions and connected to the second lines.

The first contacts and the second contacts are formed along a single line or double lines.

### BRIEF DESCRIPTION OF THE DRAWINGS

FIG. 1 is a circuit diagram illustrating a conventional electrostatic protection device for a semiconductor circuit.

FIG. 2 is a plan view illustrating the conventional electrostatic protection device for a semiconductor circuit that comprises a diode.

FIG. 3 is a plan view illustrating an electrostatic protection device for a semiconductor circuit that comprises a diode in accordance with an embodiment of the present invention.

FIGS. 4 through 6 are plan views explaining line connection structures of the electrostatic protection device for a semiconductor circuit in accordance with an embodiment of the present invention.

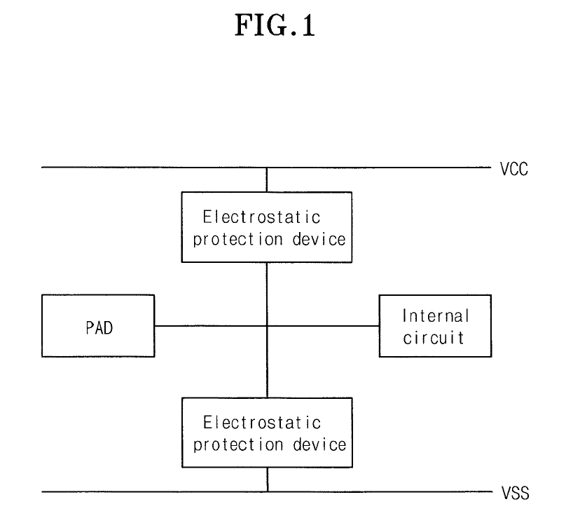

### DESCRIPTION OF SPECIFIC EMBODIMENTS

In an embodiment of the present invention, an electrostatic protection device is configured using a structure that maintains the perimeter as it is and reduces the junction area in comparison with the conventional art. In this case, since the perimeter is maintained as it is, the electrostatic protection capability of the electrostatic protection device is not decreased. Since the capacitance of the electrostatic protection device can be decreased through the reduction of the junction area, it is possible to realize an electrostatic protection device that is appropriate to a circuit operating at high speed. Further, in the electrostatic protection device according to an embodiment of the present invention, because electrostatic discharge current is dispersed in an emission type, the current density can be decreased, and a local current concentration phenomenon can be prevented, whereby electrostatic protection capability is improved.

Hereafter, an electrostatic protection device for a semiconductor circuit in accordance with an embodiment of the present invention will be described with reference to the attached drawings.

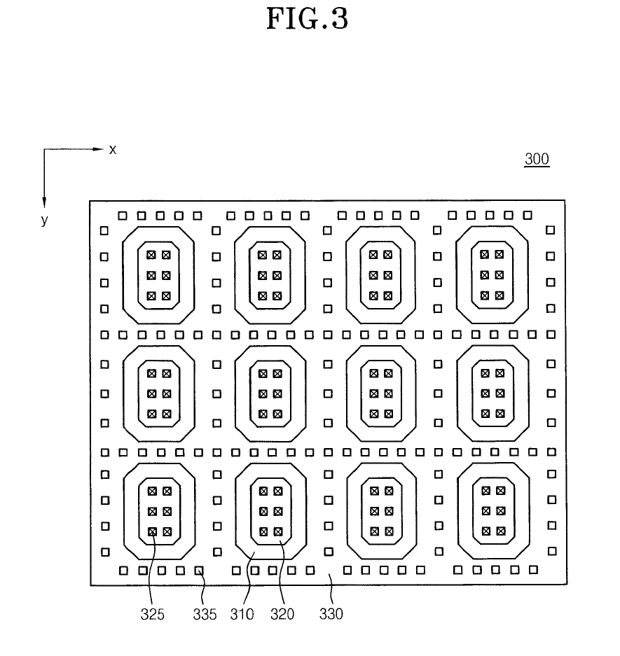

FIG. 3 is a plan view illustrating an electrostatic protection device for a semiconductor circuit that comprises a diode, in accordance with an embodiment of the present invention. Referring to FIG. 3, an electrostatic protection device for a semiconductor circuit includes second conductivity type diffusion regions 320 that are formed on the surface of the first conductivity type semiconductor substrate 300 at regular intervals into a dot type. Each second conductivity type diffusion region 320 has the sectional shape of a polygon in which each corner is of an angle greater than 90°. For example, the second conductivity type diffusion regions 320 have the sectional shape of an octagon. Also, each second conductivity type diffusion region has the sectional shape of a quadrangle having rounded corners. (Not shown) The second conductivity type diffusion regions 320 are arranged such that the distance between two second conductivity type diffusion regions 320, which adjoin each other in the widthwise direction thereof, that is, in the direction of the Y-axis as shown in FIG. 3, is less than the width of each second conductivity type diffusion region 320.

Isolation structures 310 are formed on the surface of the semiconductor substrate 300 such that they surround the second conductivity type diffusion regions 320. First conductivity type diffusion regions 330 are formed on the surface of the semiconductor substrate 300 outside of the second conductivity type diffusion regions 320 and isolation regions 310.

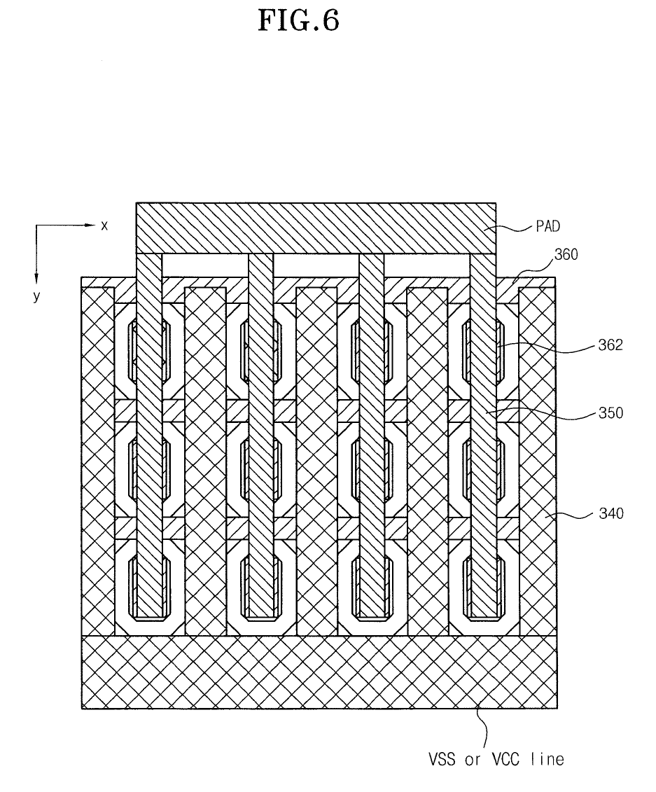

A plurality of first lines 340 (see FIG. 6) are formed such that they are brought into contact with the first conductivity type diffusion regions 330 and are connected to a ground line (VSS) or a source voltage supply line (VCC). A plurality of second lines 350 (see FIG. 6) are formed such that they are brought into contact with the second conductivity type diffusion regions 320 and are connected to a pad, designated by ‘PAD’ as shown in FIG. 6.

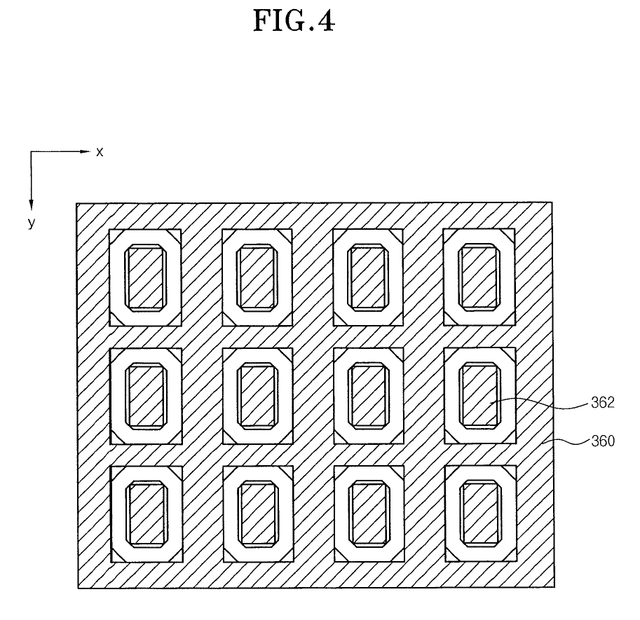

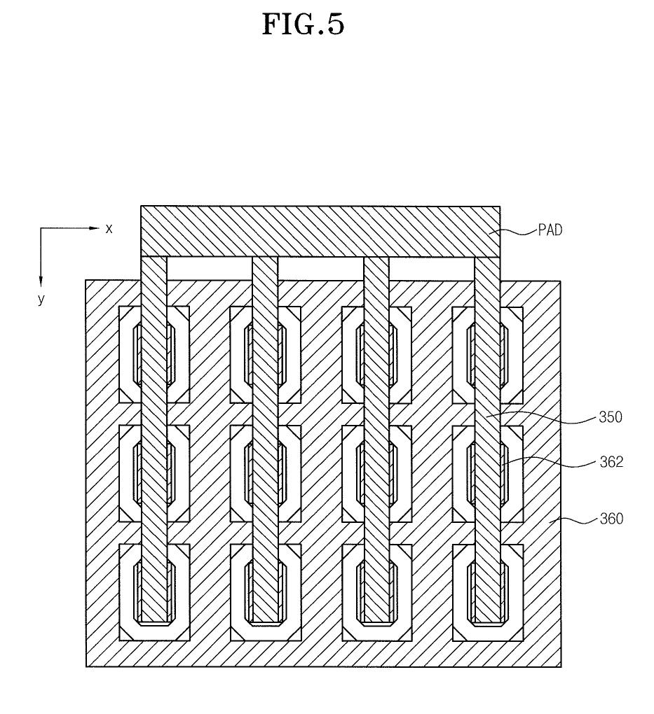

In order to ensure easy connection between the first conductivity type diffusion regions 330 of FIG. 3 and the first lines 340 of FIG. 6, a connection line 360, now referring to FIG. 4, is formed on the first conductivity type diffusion regions 330 in the shape of a matrix. As can be readily seen from FIG. 6, the first lines 340 are formed such that they are brought into contact with portions of the connection line 360, which extend in the direction of the Y-axis. Further, in order to ensure easy connection between the second conductivity type diffusion regions 320 and the second lines 350, connection patterns 362 as shown in FIG. 4 are formed on the second conductivity type diffusion regions 320. As can be readily seen from FIGS. 5-6, the second lines 350 are formed such that they are brought into contact with the connection patterns 362, which are arranged in the direction of the Y-axis.

The connection line 360 including the connection patterns 362 (as shown in FIG. 4), the first lines 340 (as shown in FIG. 6), and the second lines 350 (as shown in FIGS. 5-6) are respectively formed on different layers.

In FIG. 3, the reference numeral 335 designates a plurality of first contacts, which are formed on the first conductivity type diffusion regions 330 and connected to the first lines 340, and 325 designates a plurality of second contacts, which are formed on the second conductivity type diffusion regions 320 and connected to the second lines 350. At this time, the first contacts 335 and the second contacts 325 can be formed along a single line or double lines.

As described above, in an embodiment of the present invention, the second conductivity type diffusion regions 320, which are connected to the pad, are formed not into a bar type but into a dot type spaced apart at regular intervals and of a decreased size in comparison to those of the conventional art. Further, the first conductivity type diffusion regions 330 are formed on the surface of the semiconductor substrate 300 between the second conductivity type diffusion regions 320, which extend in the direction of the Y-axis. At this time, the second conductivity type diffusion regions 320 are formed such that the distance between two second conductivity type diffusion regions 320, which adjoin each other in the widthwise direction thereof, that is, in the direction of the Y-axis, is less than the width of each second conductivity type diffusion region 320.

In this case, while the area of each second conductivity type diffusion region 320 is reduced, the effective perimeter of the second conductivity type diffusion regions 320 is increased. This will be mathematically explained below in detail.

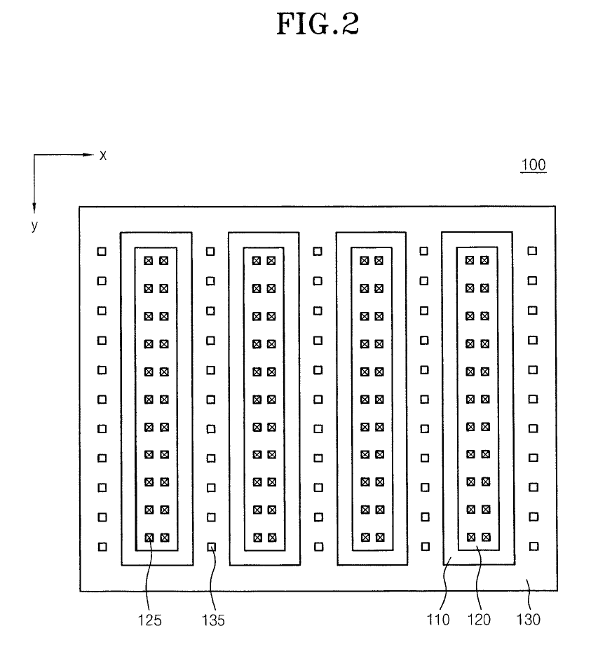

When assuming the X-axis length and the Y-axis length of the second conductivity type diffusion regions 120 having the sectional shape of a bar in FIG. 2, which illustrates the conventional art, are respectively 1 and 10, the total effective perimeter of the second conductivity type diffusion regions 120 is 20, and the total area thereof is 10. Here, the X-axis length of the second conductivity type diffusion regions 120 is not included in the effective perimeter because the first contacts 135 are not formed in the direction of the X-axis in the conventional art.

On the other hand, when assuming the X-axis length and the Y-axis length of the second conductivity type diffusion regions 320 having the shape of a dot in FIG. 3, are respectively 1 and 3, and the distance between two second conductivity type diffusion regions 320 adjoining each other is 1, the total effective perimeter of the second conductivity type diffusion regions 320 is 24, and the total area thereof is 9.

Accordingly, in the present invention, as the second conductivity type diffusion regions 320 are formed into a dot type, while the area of the second conductivity type diffusion regions 320 is reduced, the effective perimeter thereof is increased. Also, upon electrostatic discharge operation of the electrostatic protection device, static electricity can flow in both the direction of the X-axis and the direction of the Y-axis. Therefore, in the present invention, since the area of the second conductivity type diffusion regions 320 is reduced, input capacitance is decreased. Moreover, since the effective perimeter of the second conductivity type diffusion regions 320 is increased, current drivability, that is, electrostatic protection characteristics, are improved.

Also, in an embodiment of the present invention, because the second conductivity type diffusion regions 320 are shaped like an octagon in which each corner has an angle greater than 90°, it is possible to mitigate the effects of an electric field concentration phenomenon, which may occur in the corner portions of the second conductivity type diffusion regions 320. Thus, the present invention prevents a local increase in resistance due to the electric field concentration of the corner portions of the second conductivity type diffusion regions 320 and the melting of the lines, thereby improving the reliability and operational characteristics of the electrostatic protection device.

As is apparent from the above description, in the present invention, when configuring an electrostatic protection device comprising a diode, diffusion regions (anodes) that are connected to the pad are formed into a dot type, such that the area of each diffusion region is reduced and an effective perimeter thereof is increased. Hence, electrostatic discharge characteristics are improved and input capacitance by the electrostatic protection device is decreased without degradation of current driving characteristics. Therefore, according to the present invention, it is possible to realize an electrostatic protection device with low input capacitance and improved reliability, as required in highly integrated products operating at a high speed.

Although a specific embodiment of the present invention has been described for illustrative purposes, those skilled in the art will appreciate that various modifications, additions and substitutions are possible, without departing from the scope and the spirit of the invention as disclosed in the accompanying claims.

What is claimed is:

1. An electrostatic protection device for a semiconductor circuit for protecting an internal circuit from static electricity applied to a pad, comprising:
a first conductivity type semiconductor substrate;
second conductivity type diffusion regions formed on the surface of the semiconductor substrate at regular intervals into a dot type;
isolation structures formed on the surface of the semiconductor substrate to respectively surround the second conductivity type diffusion regions; and
first conductivity type diffusion regions formed on the surface of the semiconductor substrate outside of the second conductivity type diffusion regions and the isolation regions.

2. The device according to claim 1, wherein each second conductivity type diffusion region has the sectional shape of a polygon with corners each having an angle greater than 90°.

3. The device according to claim 2, wherein each second conductivity type diffusion region has the sectional shape of an octagon.

4. The device according to claim 1, wherein each second conductivity type diffusion region has the sectional shape of a quadrangle having rounded corners.

5. The device according to claim 1, wherein the distance between two second conductivity type diffusion regions, which adjoin each other in a widthwise direction thereof, is less than the width of each second conductivity type diffusion region.

6. The device according to claim 1, further comprising:
first lines formed to be connected to the first conductivity type diffusion regions; and
second lines formed to be connected to the second conductivity type diffusion regions.

7. The device according to claim 6, further comprising:
a connection line located between the first conductivity type diffusion regions and the first lines, and formed to have the shape of a matrix; and
connection patterns located between the second conductivity type diffusion regions and the second lines.

8. The device according to claim 6, wherein the first lines are connected to a ground line or a source voltage supply line.

9. The device according to claim 6, wherein the second lines are connected to the pad.

10. The device according to claim 6, further comprising:
a plurality of first contacts formed on the first conductivity type diffusion regions and connected to the first lines; and
a plurality of second contacts formed on the second conductivity type diffusion regions and connected to the second lines.

11. The device according to claim 10, wherein the first contacts and the second contacts are formed along a single line or double lines.
